(19) United States
(12) Patent Application Publication
(10) Pub. No.: US 2009/0159417 A1
(43) Pub. Date: Jun. 25, 2009

(54) Capacitive overcoat structure of touch panel and touch panel having the same

(75) Inventors: Kuan-Ying Lin, Hsinchu County (TW); Yih-Jer Lin, Hsinchu County (TW); Shiang-Wen Wan, Hsinchu County (TW); Chih-Yung Ting, Hsinchu County (TW)

Correspondence Address: BACON & THOMAS, PLLC, 625 SLATERS LANE, FOURTH FLOOR, ALEXANDRIA, VA, 22314-1176, US

(73) Assignee: CANDO CORPORATION, Hsinchu County (TW)

(21) Appl. No.: 12/285,646

(22) Filed: Oct. 10, 2008

(30) Foreign Application Priority Data
Dec. 25, 2007 (TW) 96149891

(51) Int. Cl. H03K 17/975

(52) U.S. Cl. 200/600

(57) ABSTRACT

An organic/inorganic composite structure is provided for serving as an overcoat of a capacitive touch panel. Such structure provides the overcoat with a capacitive property and refraction so that the sensitivity and the transparency of the touch panel are improved. Moreover, the entire thickness of the touch panel is also reduced in accordance with the present invention.

### BACKGROUND OF THE INVENTION

1. Field of the Invention

The present invention relates to a passiviation structure of a panel, and more particularly to a passivation structure of a capacitive touch panel.

2. Description of the Related Art

Touch sensing technology is broadly applied in the present electronic application for data input. In this case, the information is read out or transmitted while the user touches the screen with the finger or the stylus, so that the buttons, keyboards or joysticks, which are desired for the conventional electronic apparatus, could be omitted.

Depending on the principles adopted for sensing, the touch panels are grouped into such as resistive touch panels, capacitive touch panels, infrared (IR) touch panels and ultrasonic wave ones. Regarding the IR touch panels and the ultrasonic wave ones, an IR or ultrasonic wave transmitting unit is arranged on one side of the respective X-direction and Y-direction of the screen, and on the other side thereof a receiving unit is configured. The movement of IR-ray or ultrasonic wave would be changed while the screen is touched by the user, and the touch position is accordingly measured and determined for data input. With respect to the resistive touch panel, which is fabricated by the lamination of an upper and a lower indium tin oxide (ITO) conductive films, the voltage variation thereof is generated while the upper and the lower electrodes of ITO are conducted through the touch pressure, and is detected by a controller, so that the touch position for data input is determined. The capacitive touch panel is constructed by the transparent glass substrate with a layer of metal oxide coated thereon, where a uniformly distributed electrical field is produced throughout the surface of the substrate by the application of voltage from the four corners thereof. By detecting the capacitance variation caused by static-electric reaction between the user's finger and the electric field, the touch position for data input is determined.

In addition to the sensing device, the conventional touch panel further includes a passivation layer of resin attached thereto for protecting the electrode structure of ITO. In this case, the substrate of the panel is also adoptable for serving as the passivation layer. The touch panel having such passivation layer, however, is disadvantageous in the relatively thicker thickness thereof and the relatively higher fabrication cost therefor. Moreover, the substrate is easily scratched, and the sensing device is thus damaged while the color filter and the touch sensing device are fabricated on the opposed surfaces of the substrate of such panel, so that the touch sensitivity and the refraction is inversely affected.

For overcoming the mentioned issues, it is desired in this art to provide a passivation layer structure for the capacitive touch panel so as to protect the sensing device of the panel from being damaged and increase the refraction and sensitivity thereof as well.

### SUMMARY OF THE INVENTION

It is one aspect of the present invention to provide a capacitive touch panel of an improved refraction.

It is another aspect of the present invention to provide a capacitive touch panel of an increased touch sensitivity.

It is a further aspect of the present invention to provide a capacitive touch panel with a reduced thickness.

It is still a further aspect of the present invention to provide a capacitive touch panel whose fabrication cost is reduced.

The mentioned aspects are achievable by a passivation layer structure of a capacitive property and a touch panel having such passivation layer structure that is provided according to the present invention.

In accordance with the mentioned aspects of the present invention, the provided capacitive touch panel includes a touch sensing device and a composite overcoat, where the composite overcoat is located above the touch sensing device and has a capacitive property.

In accordance with the mentioned aspects of the present invention, the passivation layer structure of a capacitive touch panel is a composite overcoat having a capacitive property where the provided composite overcoat includes an organic portion and an inorganic portion formed with a paste.

In accordance with the mentioned aspects of the present invention, the passivation layer structure of a capacitive touch panel is a light transmittable composite overcoat including an organic paste and an inorganic ceramic material.

Preferably, the composite overcoat has a solid content ranged from 5% to 30%.

Preferably, the inorganic portion includes one of a metal oxide and a silicon-based material.

Preferably, the inorganic portion is one selected from a group consisting of a silicon oxide, a titanium oxide, a barium titanate, an aluminum oxide, a lead oxide, a silicon nitride, a calcium oxide, a magnesium oxide, a beryllium oxide and a combination thereof.

Preferably, the organic portion includes an alcohol, a silane and a cellosolve.

Preferably, the alcohol of the organic portion includes one selected from a group consisting of an ethylene glycol, a hexylene glycol, an ethanol, an isopropanol and a combination thereof.

Preferably, the cellosolve of the organic portion is a butylcellosolve.

Preferably, the composite overcoat has a refractive index substantially equal to that of the touch sensing device.

Preferably, the composite overcoat has a refractive index ranged from 1.5 to 1.9.

Preferably, the composite overcoat has a pencil hardness of at least 6H.

Preferably, the composite overcoat has a dielectric constant of at least 3.

Preferably, the composite overcoat has a transmittance of at least 85%.

Preferably, the composite overcoat has a thickness ranged from 0.05 μm to 6 μm and is provided on the touch sensing device by photolithography process.

Preferably, the composite overcoat has a thickness ranged from 0.05 μm to 0.20 μm and is provided on the touch sensing device by polyimide (PI) coating.

Preferably, the composite overcoat has a thickness ranged from 0.5 μm to 5 μm and is provided on the touch sensing device by one of slit coating and spin coating.

Preferably, the composite overcoat has a thickness ranged from 3 μm to 6 μm and is provided on the touch sensing device by one of transferring printing and screen printing.

### BRIEF DESCRIPTION OF THE DRAWINGS

The above objects and advantages of the present invention will become more readily apparent to those ordinarily skilled in the art after reviewing the following detailed descriptions and accompanying drawings, in which:

FIG. 1 is a cross-sectional view schematically showing a capacitive touch panel in accordance with a preferred embodiment of the present invention;

FIG. 2 is a cross-sectional view schematically showing a capacitive touch panel in accordance with a further preferred embodiment of the present invention; and

FIGS. 3A to 3C are photographs indicating the result of the hardness test for the composite overcoat in accordance with the present invention.

### DETAILED DESCRIPTION OF THE PREFERRED EMBODIMENT

With reference to the following disclosures combined with the accompanying drawings, the magnetic shielding package structure of a. magnetic memory device according to the present invention is illustrated and understood.

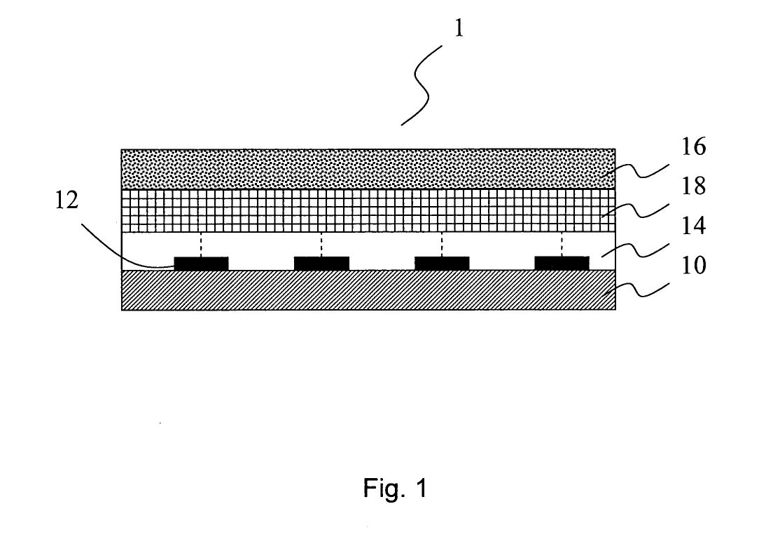

With reference to FIG. 1, the capacitive touch panel according to a preferred embodiment of the present invention is schematically illustrated. The capacitive touch panel 1 according to the present invention is constructed by a substrate 10, and on one surface thereof a black matrix (BM) layer 12, a color filter 14, and a layer of indium tin oxide (ITO) 18 serving for sensing are formed in turn. Above the layer of ITO 18, a composite overcoat 16 according to the present invention composed of an organic portion and an inorganic portion is provided, where the solid content thereof is ranged from 5% to 30%. The thickness of the composite overcoat 16 is varied within a range between 0.05 μm and 6 μm, depending on the fabrication process thereof. In more specific, the composite overcoat fabricated by polyimide (PI) coating may have a thickness ranged from 0.05 μm to 0.20 μm, while the composite overcoat fabricated by slit coating or spin coating may have a thickness ranged from 0.5 μm to 5 μm. By transferring printing or by screen printing, on the other hand, the fabricated composite overcoat may have a thickness in a range of 3˜6 μm.

According to the present invention, the organic portion of the composite overcoat 16 contains the alcohol, the silane and the cellosolve, while the inorganic portion thereof contains the ceramic material such as silicon oxides, titanium oxides, barium titanates, aluminum oxides, lead oxides, silicon nitrides, calcium oxides, magnesium oxides, beryllium oxides or the combination thereof. Additionally, the solid content of the composite overcoat 16 of the present invention is determined for complying with various conditions for the desired film-formation process and the yield thereof. In this case, the viscosity of the paste is adjusted by altering the organic content thereof, so as to be applicable in film-formation by printing and alternatively, by coating. In this preferred embodiment of the present invention, the organic portion of the composite overcoat 16 is composed of ethylene glycol or propylene glycol, hexylene glycol, ethanol, isopropanol, polysiloxane and butylcellosolve, where the inorganic portion thereof has a solid content of approximately 6%.

According to the present invention, the organic portion and the inorganic portion of the composite overcoat 16 are properly adjusted depending on the processing conditions and capacitive properties as desired. The composition of the organic portion is listed in Table 1.

TABLE 1

| | Composition 1 | Composition 2 | Composition 3 |
|---|---|---|---|
| Ethylene Glycol | 18.4% | 35.3% | |
| Propylene Glycol | | | |
| Hexylene Glycol | 36.9% | 17.7% | 60-70% |
| Ethanol | 12.8% | 15.2% | |
| Isopropanol | 2.5% | | |
| Polysiloxane | 5% | 6% | 5-10% |
| Butylcellosolve | 18.4% | 17.7% | |
| Water | | 8.1% | |

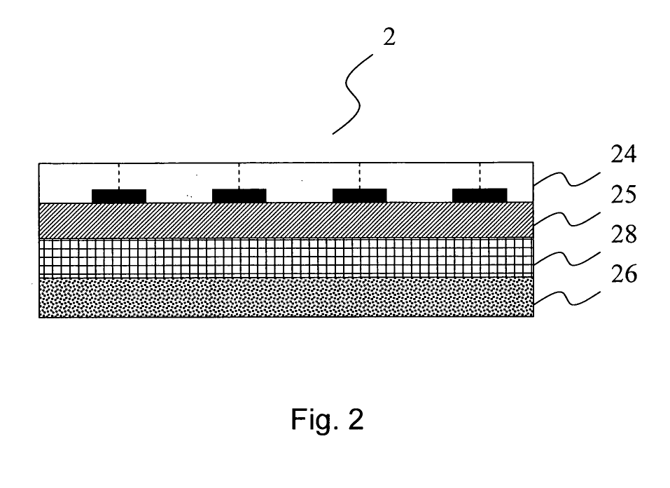

With reference to FIG. 2, the capacitive touch panel according to another preferred embodiment of the present invention is schematically illustrated. In comparison with the configuration as shown in FIG. 1, the capacitive touch panel 2 has a layer of color filter 24 and an electrode layer for sensing 28 respectively arranged on the opposed faces of the substrate 25. Such structure is subsequently covered with a composite overcoat 26 of the present invention, and accordingly the capacitive touch panel 2 of a relatively reduced thickness is obtained.

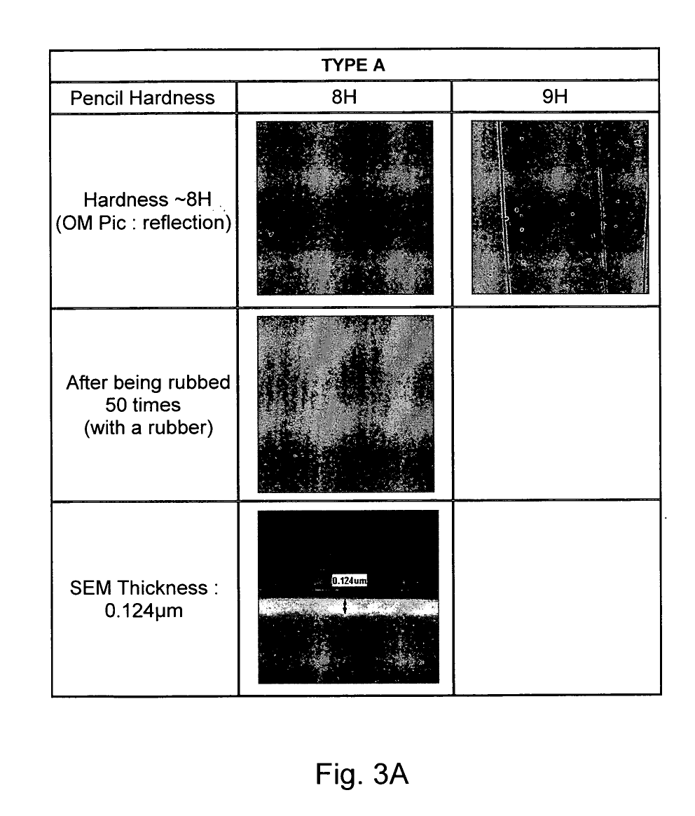

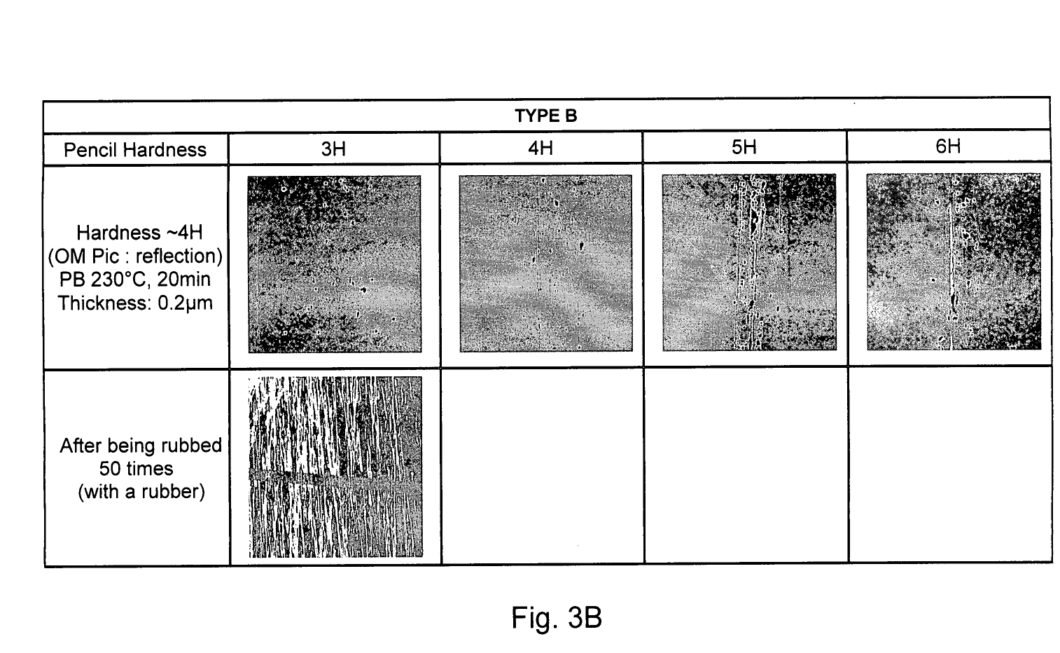

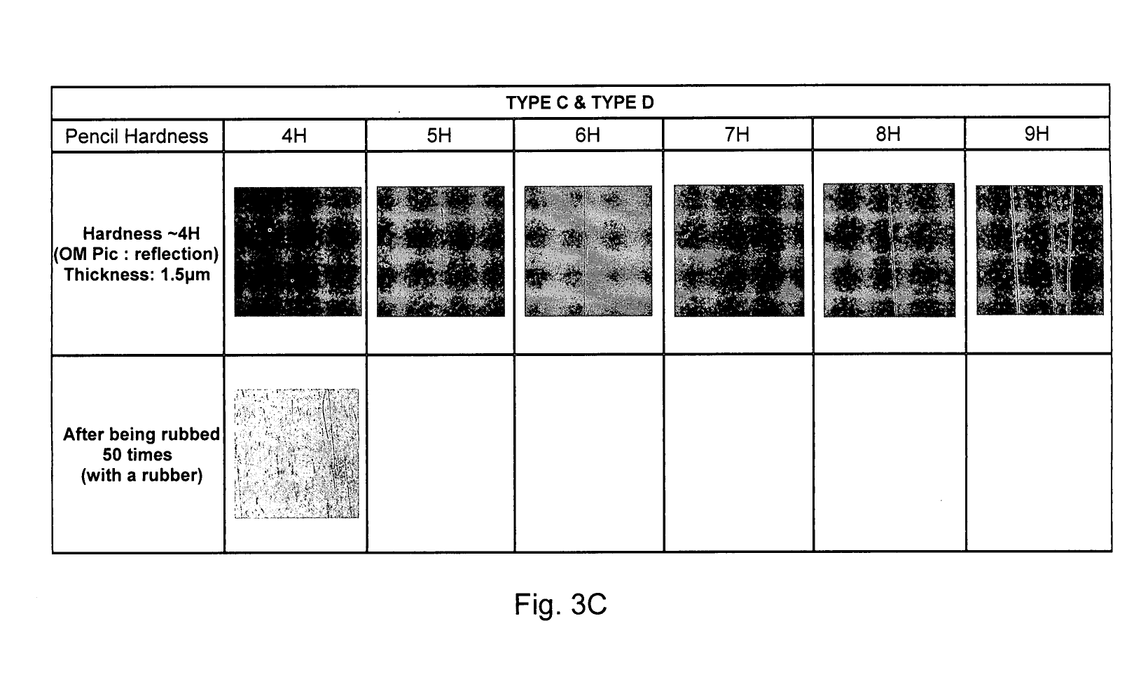

Please refer to FIGS. 3A to 3C showing the hardness test result of the respective composite overcoats of the above three compositions. It proves that the pencil hardness of the composite overcoat of a preferred embodiment according to the present invention is over 6H, even approaching 9H, which complies with the strict requirement for touch panels.

According to the present invention, the composite overcoat is produced by means of the conventional photolithography technique, or is produced by coating, transferring printing and the like for saving the fabrication cost. Moreover, the composite overcoat according to the present invention has a good ability in thermal-resisting and the acid and alkaline resistance thereof is also excellent. The fabrication of the composite overcoat of the present invention is highly compatible with the existing process for touch panel, so that the fabrication cost thereof could be further reduced. Based on the hardness test, moreover, the pencil hardness of the composite overcoat according to the present invention is over 6H, which complies well with the requirement for the present capacitive touch panels. In addition, the refraction index of the composite overcoat is higher than 1.5, which is substantially approaching that of the sensing device of the touch panel, so that the refraction thereof is increased. Furthermore, the dielectric constant of the composite overcoat is larger than 3, which exhibits an excellent capacitive property sufficiently to improve the sensitivity of the capacitive touch panel.

Consequently, the existing issues of the conventional touch panel that adopts a resin layer attached thereto or the substrate itself for serving as the passivation are overcome in the present invention. According to the present invention, the total thickness of the capacitive touch panel is reduced in a cost-effective manner, and the refraction and the sensitivity thereof are improved as well. Additionally, the sensing device of the touch panel having such composite overcoat is provided with a good protection from being damaged due to the scratch of substrate produced while the color filter and the electrode layer are respectively formed on the opposed sides of a single substrate, and the composite overcoat according to the present invention is stable enough so that the characteristics thereof would not be varied in the duration of rear-end processes.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

What is claimed is:

1. A capacitive touch panel comprising a touch sensing device and a composite overcoat, characterized by that said composite overcoat is located above said touch sensing device and has a capacitive property, where said composite overcoat comprises an organic portion and an inorganic portion formed with a paste.

2. The capacitive touch panel of claim 1, wherein said composite overcoat has a solid content ranged from 5% to 30%.

3. The capacitive touch panel of claim 1, wherein said inorganic portion comprises one of a metal oxide and a silicon-based material.

4. The capacitive touch panel of claim 1, wherein said inorganic portion is one selected from a group consisting of a silicon oxide, a titanium oxide, a barium titanate, an aluminum oxide, a lead oxide, a silicon nitride, a calcium oxide, a magnesium oxide, a beryllium oxide and a combination thereof.

5. The capacitive touch panel of claim 1, wherein said organic portion comprises an alcohol, a polysiloxane and a cellosolve.

6. The capacitive touch panel of claim 5, wherein said alcohol of said organic portion comprises one selected from a group consisting of an ethylene glycol, a hexylene glycol, an ethanol, an isopropanol and a combination thereof.

7. The capacitive touch panel of claim 5, wherein said cellosolve of said organic portion is a butylcellosolve.

8. The capacitive touch panel of claim 1, wherein said composite overcoat has a refractive index substantially equal to that of said touch sensing device.

9. The capacitive touch panel of claim 1, wherein said composite overcoat has a refractive index ranged from 1.5 to 1.9.

10. The capacitive touch panel of claim 1, wherein said composite overcoat has a pencil hardness of at least 6H.

11. The capacitive touch panel of claim 1, wherein said composite overcoat has a dielectric constant of at least 3.

12. The capacitive touch panel of claim 1, wherein said composite overcoat has a transmittance of at least 85%.

13. The capacitive touch panel of claim 1, wherein said composite overcoat has a thickness ranged from 0.05 μm to 6 μm.

14. The capacitive touch panel of claim 1, wherein said composite overcoat has a thickness ranged from 0.05 μm to 0.20 μm.

15. The capacitive touch panel of claim 14, wherein said composite overcoat is provided on the touch sensing device by polyimide (PI) coating.

16. The capacitive touch panel of claim 1, wherein said composite overcoat has a thickness ranged from 0.5 μm to 5 μm.

17. The capacitive touch panel of claim 16, wherein said composite overcoat is provided on the touch sensing device by one of slit coating and spin coating.

18. The capacitive touch panel of claim 1, wherein said composite overcoat has a thickness ranged from 3 μm to 6 μm.

19. The capacitive touch panel of claim 18, wherein said composite overcoat is provided on the touch sensing device by one of transferring printing and screen printing.

20. The capacitive touch panel of claim 1, wherein said composite overcoat is provided on the touch sensing device by photolithography process.
